(19) United States
(12) Patent Application Publication
(10) Pub. No.: US 2012/0247818 A1
(43) Pub. Date: Oct. 4, 2012

(54) PRINTED WIRING BOARD

(75) Inventors: Takema Adachi, Ogaki-shi (JP); Toshiki Furutani, Ogaki-shi (JP); Liyi Chen, Ogaki-shi (JP)

(73) Assignee: IBIDEN CO., LTD., Ogaki-shi (JP)

(21) Appl. No.: 13/425,585

(22) Filed: Mar. 21, 2012

Related U.S. Application Data
(60) Provisional application No. 61/468,756, filed on Mar. 29, 2011.

(51) Int. Cl. H05K 1/09; H05K 1/11

(52) U.S. Cl. 174/257; 174/258

(57) ABSTRACT

A printed wiring board includes a core substrate, a first conductive layer on a first surface of the substrate, a second conductive layer on a second surface of the substrate, and a through-hole conductor connecting the first and second conductive layers. The substrate has an insulation structure and a metal layer, the metal layer has opening through which the conductor passes and has side wall recessed into the metal layer and forming the opening, the structure has first resin layer on one side of the metal layer, second resin layer on the opposite side and filler filling the opening, the conductor has first portion in the first layer and second portion in the second layer, the first and second portions are connected in the filler, the first portion is tapered from the first toward second conductive layers, and the second portion is tapered from the second toward first conductive layers.

### CROSS-REFERENCE TO RELATED APPLICATIONS

The present application is based on and claims the benefit of priority to U.S. Application No. 61/468,756, filed Mar. 29, 2011, the entire contents of which are incorporated herein by reference.

### BACKGROUND OF THE INVENTION

1. Field of the Invention

The present invention relates to a printed wiring board having a metal layer with an opening, filler resin formed in the opening of the metal layer, resin insulation layers sandwiching the metal layer, and a through-hole conductor.

2. Discussion of the Background

Japanese Laid-Open Patent Publication No. 2004-140216 describes a printed wiring board having a metal layer with a penetrating hole. A through-hole conductor with a straight shape is formed in the penetrating hole of the metal layer. The entire contents of this publication are incorporated herein by reference.

### SUMMARY OF THE INVENTION

According to one aspect of the present invention, a printed wiring board includes a core substrate having a first surface and a second surface on the opposite side of the first surface, a first conductive layer formed on the first surface of the core substrate, a second conductive layer formed on the second surface of the core substrate, and a through-hole conductor formed through the core substrate and connecting the first conductive layer and the second conductive layer. The core substrate includes an insulation structure and a metal layer positioned inside the insulation structure, the metal layer has an opening portion through which the through-hole conductor passes and has a side wall recessed into the metal layer and forming the opening portion, the insulation structure has a first resin insulation layer portion formed on one side of the metal layer, a second resin insulation layer portion formed on the opposite side of the metal layer and a filler resin portion filling the opening portion, the through-hole conductor has a first portion in the first resin insulation layer portion and a second portion in the second resin insulation layer portion, the first and second portions reach inside the filler resin portion and are connected in the filler resin portion, the first portion is tapered from the first conductive layer toward the second conductive layer, and the second portion is tapered from the second conductive layer toward the first conductive layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1(A)-1(F) are views of steps showing a method for manufacturing a multilayer printed wiring board according to a first embodiment of the present invention;

FIGS. 2 (A)-2(E) are views of steps showing the method for manufacturing a multilayer printed wiring board according to the first embodiment;

FIGS. 3 (A)-3(D) are views of steps showing the method for manufacturing a multilayer printed wiring board according to the first embodiment;

FIGS. 4 (A)-4(C) are views of steps showing the method for manufacturing a multilayer printed wiring board according to the first embodiment;

FIGS. 5 (A)-5(B) are views of steps showing the method for manufacturing a multilayer printed wiring board according to the first embodiment;

FIG. 6 is a cross-sectional view of a multilayer printed wiring board according to the first embodiment;

FIG. 7 is a cross-sectional view showing a state in which an IC chip is mounted on the multilayer printed wiring board shown in FIG. 6;

FIGS. 8 (A)-8(B) are views showing sizes of a penetrating hole and an opening;

FIG. 9 is a view showing a positional relationship of an opening in the metal layer, a first opening and a second opening, and a positional relationship of the gravity center of each opening;

FIG. 10 is a view showing diameters of a penetrating hole;

FIGS. 11(A)-11(F) are examples of first and second opening portions;

FIGS. 12 (A)-12(C) are cross-sectional views of a metal layer;

FIGS. 13 (A)-13(B) are views illustrating openings of a metal layer;

FIGS. 14 (A)-14(B) are views showing a through-hole conductor of the conventional art and a through-hole conductor of the first embodiment;

FIGS. 15 (A)-15(B) are views showing positions of connected portions;

FIG. 16 is a view showing a recessed amount (Re);

FIGS. 17 (A)-17(D) are examples of a method for forming an opening in the metal layer; and

FIGS. 18 (A)-18(C) are examples of the cross-sectional view of a penetrating hole.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

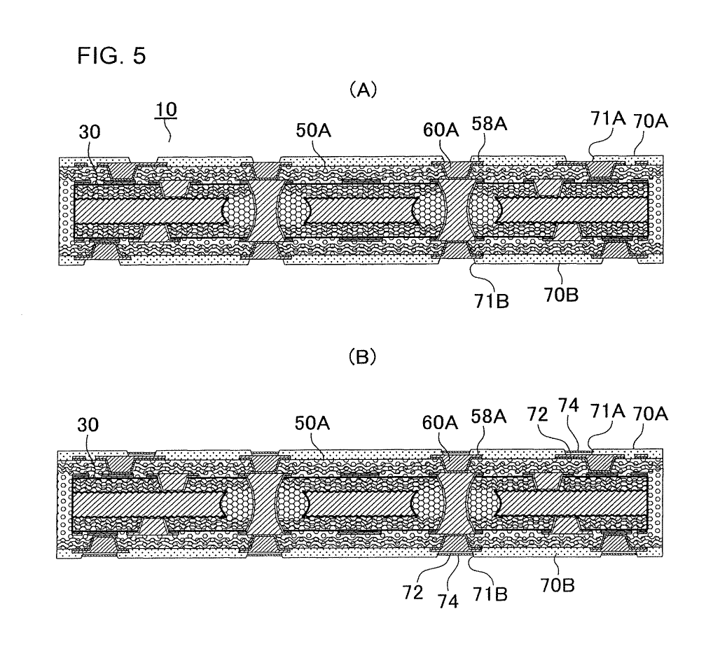

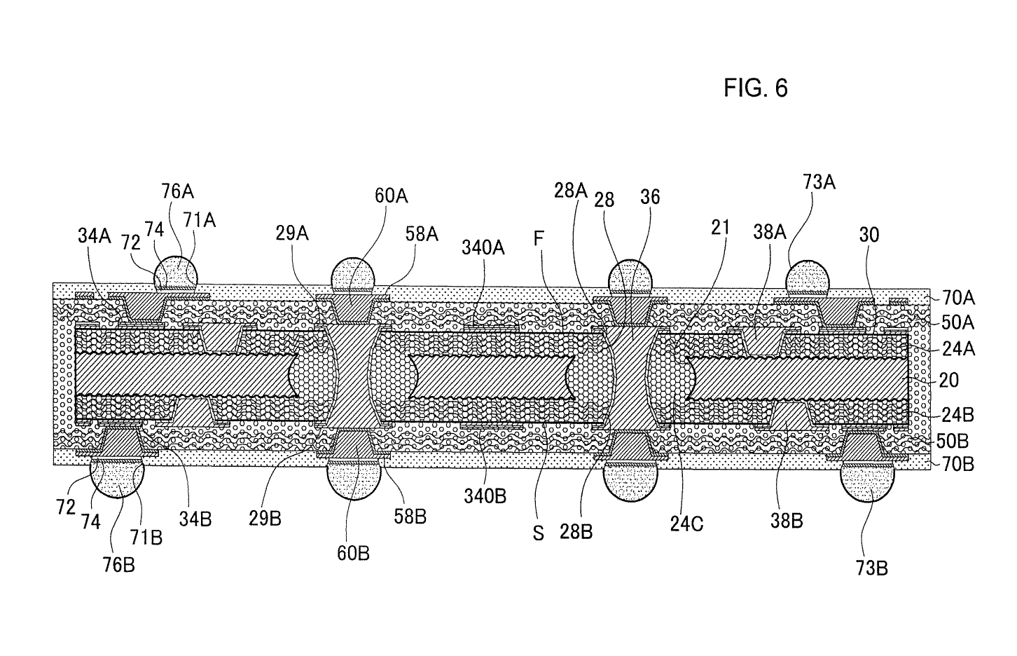

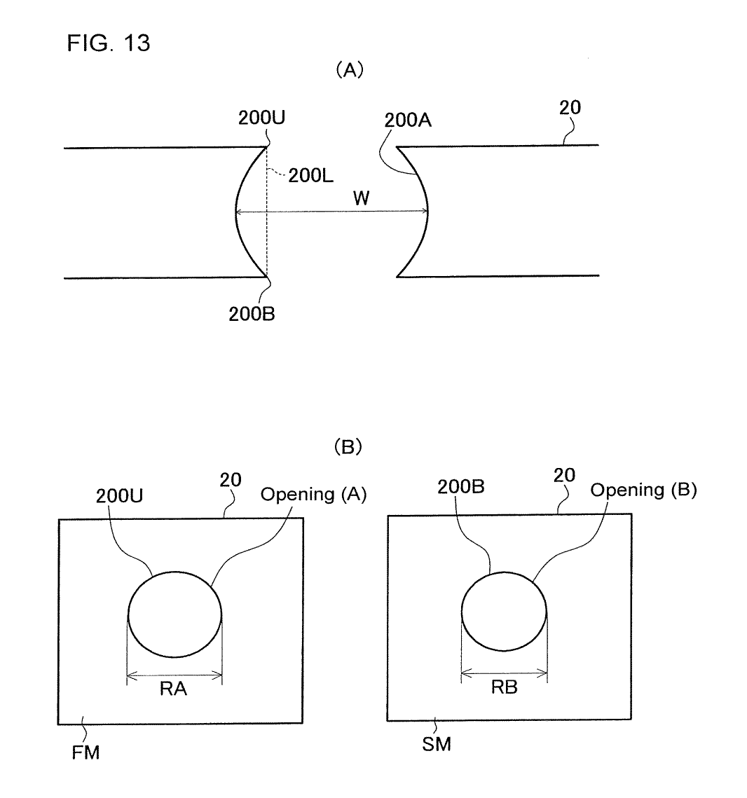

Multilayer printed wiring board 10 according to the first embodiment (see FIG. 5(A)) is described with reference to FIG. 6. FIG. 6 shows a cross-sectional view of multilayer printed wiring board 10. Multilayer printed wiring board 10 is formed with printed wiring board 30 and buildup layers on the printed wiring board. Printed wiring board 30 has the following: metal layer 20 having opening 21; filler resin (24C) filled in opening 21; first resin insulation layer (24A) and second resin insulation layer (24B) sandwiching metal layer 20; first conductive layer (34A) on the first resin insulation layer; second conductive layer (34B) on the second resin insulation layer; and through-hole conductor 36. The first conductive layer and the second conductive layer include lands (29A, 29B) formed around a through-hole conductor and multiple conductive circuits (340A, 340B). Metal layer 20 has a first surface and a second surface opposite the first surface. Also, the metal layer has opening 21 which reaches the second surface from the first surface. Side wall (200A) of the metal layer exposed through opening 21 is curved inward (FIG. 13(A)). FIG. 13 shows a cross-sectional view (FIG. 13(A)) and a plan view (FIG. 13(B)) of the metal layer. (200A) in FIG. 13(A) shows a side wall (wall surface) of the metal layer exposed through opening 21. As shown in FIG. 13(A), the side wall of the metal layer is recessed inward from line (200L) which connects upper end (200U) and lower end (200B) of the side wall. The metal layer has opening (A) on the first surface and opening (B) on the second surface (FIG. 13(B)). In FIG. 13(B), diameter (RA) of opening (A) is the same as diameter (RB) of opening (B).

The first resin insulation layer has an upper surface and a lower surface opposite the upper surface and is formed on the first surface of the metal layer and on the filler resin. The lower surface of the first resin insulation layer faces the first surface of the metal layer. The second resin insulation layer has a main surface and a secondary surface opposite the main surface and is formed on the second surface of the metal layer and on the filler resin. The secondary surface of the second resin insulation layer faces the second surface of the metal layer. First conductive layer (34A) is formed on the upper surface of the first resin insulation layer, and second conductive layer (34B) is formed on the main surface of the second resin insulation layer.

Through-hole conductor 36 is formed in penetrating hole 28 which penetrates through the first resin insulation layer, the filler resin and the second resin insulation layer. The penetrating hole is made up of first opening portion (28A) and second opening portion (28B). The first opening portion penetrates through the first resin insulation layer and reaches the filler resin. Then, the first opening portion becomes thinner from the upper surface of the first resin insulation layer toward the main surface of the second resin insulation layer. The second opening portion penetrates through the second resin insulation layer and reaches the filler resin. Then, in the filler resin, the second opening portion is connected to the first opening portion. Also, the second opening portion becomes thinner from the main surface of the second resin insulation layer toward the upper surface of the first resin insulation layer.

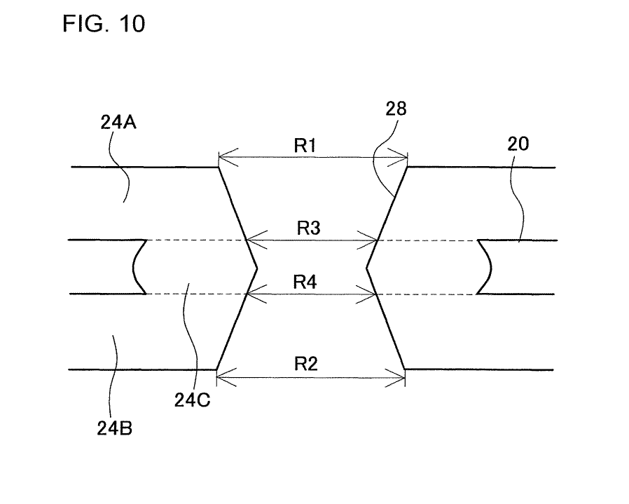

The first opening portion has first opening (280A) on the upper surface of the first resin insulation layer, and the second opening portion has second opening (280B) on the main surface of the second resin insulation layer. FIG. 10 shows a cross-sectional view and the diameters of penetrating hole 28. (R1) is the diameter of first opening (280A) and (R2) is the diameter of second opening (280B). Also, the diameter of the penetrating hole at the location parallel to the first surface of the metal layer is shown as (R3) in FIG. 10. The diameter of the penetrating hole at the location parallel to the second surface of the metal layer is shown as (R4) in FIG. 10. Between diameter (R1) of first opening (280A) and diameter (R2) of second opening (280B), the greater diameter corresponds to the diameter of the through-hole conductor.

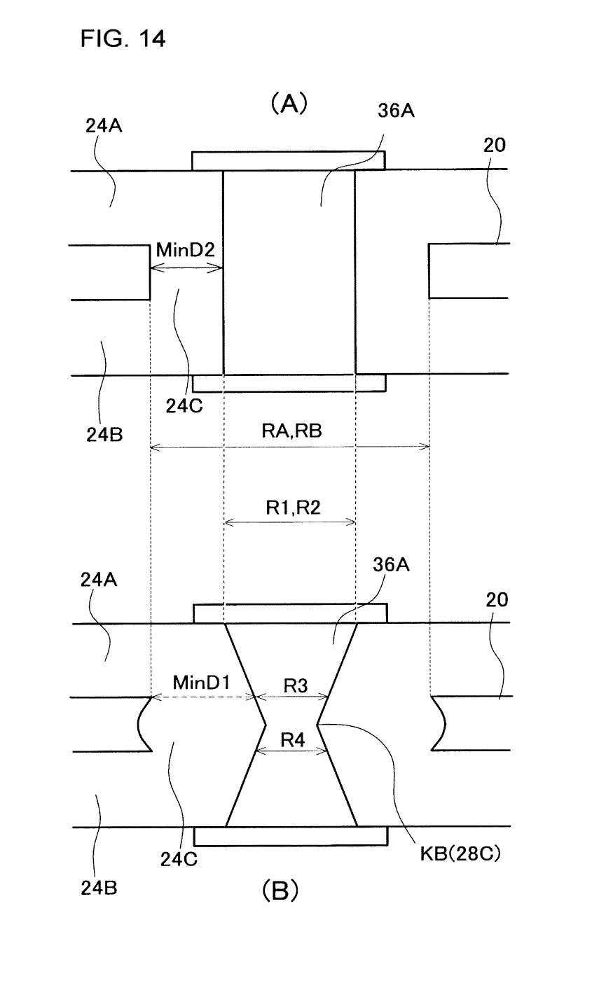

FIG. 14 shows an example in which a through-hole conductor of the conventional art (FIG. 14(A)) and a through-hole conductor of the first embodiment (FIG. 14(B)) have the same diameter, and an opening of the metal layer in the conventional art and an opening of the metal layer in the first embodiment have the same diameter (RA, RB). In FIG. 14, (R1) is equal to (R2), and (R3) is equal to (R4). Also, (RA) is equal to (RB). FIG. 14 shows the minimum distance (MinD) between a through-hole conductor and a metal layer. (MinD1) corresponds to the minimum distance in the first embodiment, and (MinD2) corresponds to the minimum distance in the conventional art. (MinD1) is greater than (MinD2). Therefore, insulation reliability is better in the first embodiment than in the conventional art. According to a printed wiring board of the first embodiment, short circuiting is less likely to occur between the metal layer and the through-hole conductor than in the conventional art when the metal layer is used as a power-source layer or a ground layer.

In addition, the minimum distance in a printed wiring board of the first embodiment may be equal to (MinD2). In such a case, since the volume of the metal layer in the printed wiring board increases, heat dissipation improves. Thus, an IC chip with greater power consumption may be mounted on a printed wiring board of the first embodiment. For example, a printed wiring board of the first embodiment is used as a base substrate for package on package (POP). Then, an IC chip with power consumption of 2 watts or greater is mounted on a printed wiring board of the first embodiment. Malfunctions seldom occur in a memory mounted on the upper substrate of the POP. In a printed wiring board of the first embodiment, the size of the printed wiring board is made smaller by decreasing the (MinD).

A through-hole conductor in a printed wiring board of the first embodiment has bent portion (28C) at the connected point of the first opening portion and the second opening portion. Since stress tends to concentrate in bent portion (KB), cracking originating in the bent portion tends to occur in the filler resin. However, as shown in FIG. 14(B), the side wall of the through-hole conductor and the side wall of the metal layer are recessed in opposite directions in the first embodiment. Thus, the distance is made longer between the bent portion of the through-hole conductor and the metal layer. Accordingly, cracking originating in the bent portion tends not to reach the metal layer. As a result, short circuiting seldom occurs between the through-hole conductor and the metal layer in a printed wiring board of the first embodiment. In the first embodiment, minimum distance (MinD1) is made smaller. If the minimum distance is small, since heat tends to be transferred from the through-hole conductor toward the metal layer, a printed wiring board of the first embodiment is excellent in heat dissipation. Also, its size is made smaller than in the conventional art. In the present application, printed wiring board 30 is also referred to as core substrate 30. The upper surface of the first resin insulation layer is the same surface as the first surface of the core substrate, and the main surface of the second resin insulation layer is the same surface as the second surface of the core substrate.

Upper interlayer resin insulation layer (50A) is formed on first surface (F) of core substrate 30 and on the first conductive layer. Upper interlayer resin insulation layer (50A) has a first surface and a second surface opposite the first surface. The second surface of upper interlayer resin insulation layer (50A) faces the first surface of the core substrate. Conductive circuit (58A) is formed on the first surface of upper interlayer resin insulation layer (50A). Conductive circuit (58A) on upper interlayer resin insulation layer (50A) and the first conductive layer or a through-hole conductor are connected by via conductor (60A) penetrating through upper interlayer resin insulation layer (50A).

Lower interlayer resin insulation layer (50B) is formed on second surface (S) of core substrate 30 and on the second conductive layer. Lower interlayer resin insulation layer (50B) has a first surface and a second surface opposite the first surface. The second surface of lower interlayer resin insulation layer (50B) faces the second surface of the core substrate. Conductive circuit (58B) is formed on the first surface of lower interlayer resin insulation layer (50B). Conductive circuit (58B) on lower interlayer resin insulation layer (50B) and the second conductive layer or a through-hole conductor are connected by via conductor (60B) penetrating through lower interlayer resin insulation layer (50B).

Upper solder-resist layer (70A) is formed on the first surface of upper interlayer resin insulation layer (50A), and lower solder-resist layer (70B) is formed on the first surface of lower interlayer resin insulation layer (50B). Upper and lower solder-resist layers (70A, 70B) have openings (71A, 71B) that expose via conductors (60A, 60B) and conductive circuits (58A, 58B). The upper surfaces of the via conductors and conductive circuits exposed through openings (71A, 71B) work as solder pads. Solder bumps (76A, 76B) are formed on solder pads.

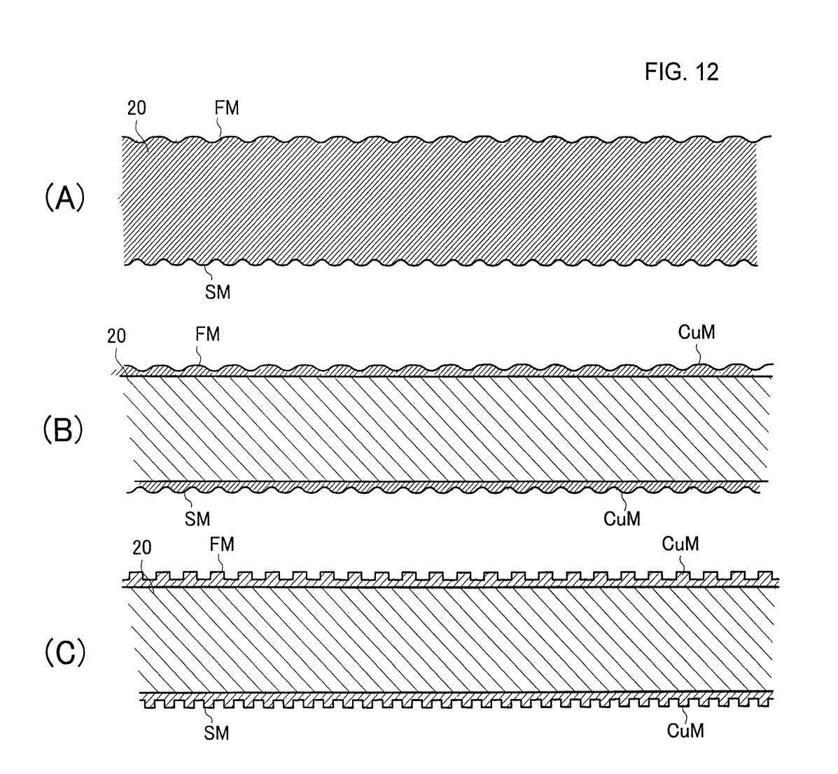

Magnified views of metal layers 20 are shown in FIG. 12. As the material for metal layer 20, copper or an Fe—Ni alloy is preferred. The thickness of metal layer 20 is 20 μm˜100 μm, and the first surface and the second surface are roughened. Adhesiveness improves between the metal layer and a first resin insulation layer and a second resin insulation layer laminated on the surfaces of the metal layer. The Rz of the roughness is 2.0˜6.0 μm. If the Rz is smaller than 2.0 μm, adhesiveness is low, and if the Rz is greater than 6.0 μm, the flatness of resin insulation layers declines. The roughness of each surface is measured using a laser microscope made by Keyence, for example.

The roughness may be different on the first surface and the second surface of the metal layer. In such a case, an IC chip is mounted on the first surface of the metal layer, the first surface is roughened at Rz of 3.5˜6.0 μm, and the second surface is roughened at Rz of 2.0˜3.0 μm. An electronic component with a smaller thermal expansion coefficient such as an IC chip is mounted on the first-surface side. Accordingly, the stress exerted at the interface of the first surface of the metal layer and the first resin insulation layer is greater than the stress exerted at the interface of the second surface of the metal layer and the second resin insulation layer. Thus, the Rz of the first surface is preferred to be greater than the Rz of the second surface.

Metal layer 20 of core substrate 30 is used as power source or ground. By forming via conductor (38A) in the first resin insulation layer to connect the first conductive layer and the metal layer, the metal layer works as power source or ground. Alternatively, by forming via conductor (38B) in the second resin insulation layer to connect the second conductive layer and the metal layer, the metal layer works as power source or ground. The core substrate may have both via conductor (38A) and via conductor (38B).

When the first or second resin insulation layer is laminated on the metal layer, resin from at least either the first or the second insulation layer fills an opening of the metal layer. When the first or second resin insulation layer contains inorganic particles, opening 21 is filled with resin containing inorganic particles. Then, the resin is cured and filler resin (24C) is formed in opening 21. The filler resin does not include reinforcing material such as glass cloth.

Through-hole conductor 36 formed in core substrate 30 in FIG. 6 is formed with metal that fills the penetrating hole. The metal is formed by plating, for example. Copper is preferred as the metal.

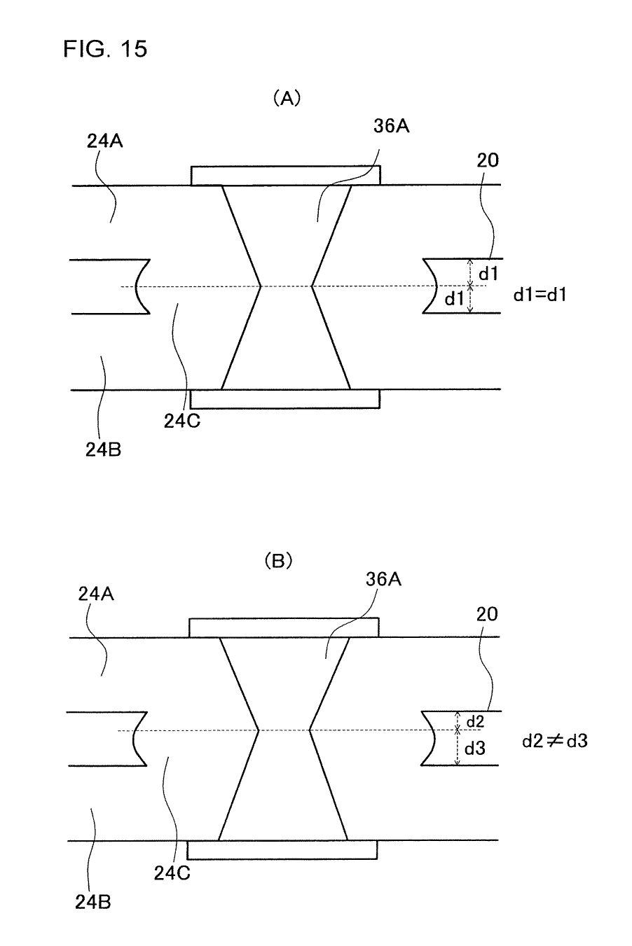

A through-hole conductor of the first embodiment has connected portion (KB) (FIG. 14). The connected portion is also referred to as the bent portion. The connected portion is where the first opening portion and the second opening portion are connected. In the first embodiment, it is also an option for the position of the connected portion to correspond to the center of the metal layer in a cross-sectional direction (FIG. 15(A)). The center is positioned at an equal distance from the first surface and the second surface of the metal layer. The position of the connected portion is preferred to be different from the center of the metal layer (FIG. 15(B)).

A cross section of through-hole conductor 36 is shaped in an hourglass form. Distance (W) between wall surfaces of metal layer 20 exposed through opening 21 becomes longer from the first surface of the metal layer toward the center of the metal layer, and reaches its maximum at a predetermined spot. Then, distance (W) between wall surfaces becomes shorter from the predetermined spot toward the second surface of the metal layer (FIG. 13(A)). Wall surfaces (side walls) of metal layer 20 are curved surfaces and are formed with an arc shape.

The thickness of the metal layer in the first embodiment is preferred to be 20˜100 μm. If the thickness of the metal layer is less than 20 μm, it is difficult to form the connected portion of a through-hole conductor between the first surface and the second surface of the metal layer. Namely, the connected portion would be formed in the first or second resin insulation layer. If the thickness of the metal layer increases, the volume of the filler resin formed between a through-hole conductor and the wall surfaces of the metal layer increases. A through-hole conductor of the first embodiment has a connected portion. Since the connected portion is narrow, it is thought that heat is generated at such a location. The greater the volume of the filler resin, the more the heat is thought to accumulate in the filler resin. Then, the filler resin expands, and force is exerted at the connected portion of a through-hole conductor. When such force increases, defects such as cracking are occur in the through-hole conductor or the filler resin. If the thickness of the metal layer is 100 μm or less, such defects seldom occur.

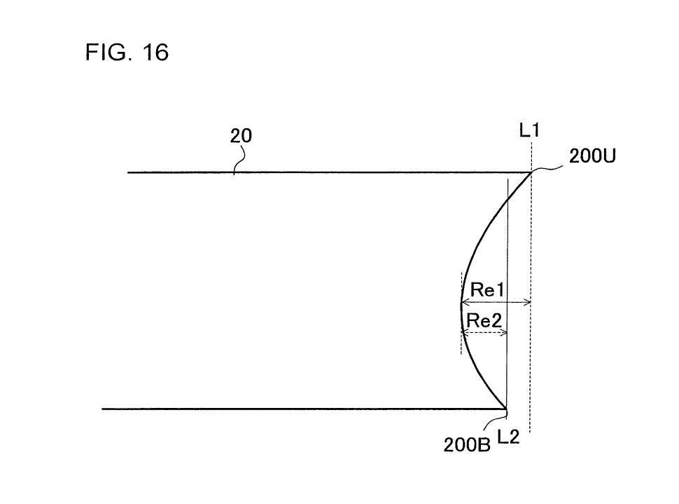

Recessed amount (Re) of the metal layer is preferred to be ⅔˜⅛ the thickness of the metal layer (FIG. 16). (Re) is the greater value between distance (Re1) from straight line (L1), which passes through upper end (200U) of the metal layer and is perpendicular to the first surface of the metal layer, to the farthest wall surface from straight line (L1), and distance (Re2) from straight line (L2), which passes through lower end (200B) of the metal layer and is perpendicular to the first surface of the metal layer, to the farthest wall surface from straight line (L2). If (Re) is in such a range, a printed wiring board with excellent heat dissipation is provided. Also, defects such as cracking seldom occur in a through-hole conductor or filler resin. In addition, metal layer 20 may be roughened at wall surfaces. Since filler resin and the wall surfaces of the metal layer are adhered, cracking seldom occurs in the filler resin. First and second resin insulation layers (24A, 24B) may include core material as well as inorganic particles. The difference in thermal expansion coefficients with metal layer 20 is reduced, and cracking is suppressed from occurring during heat cycles.

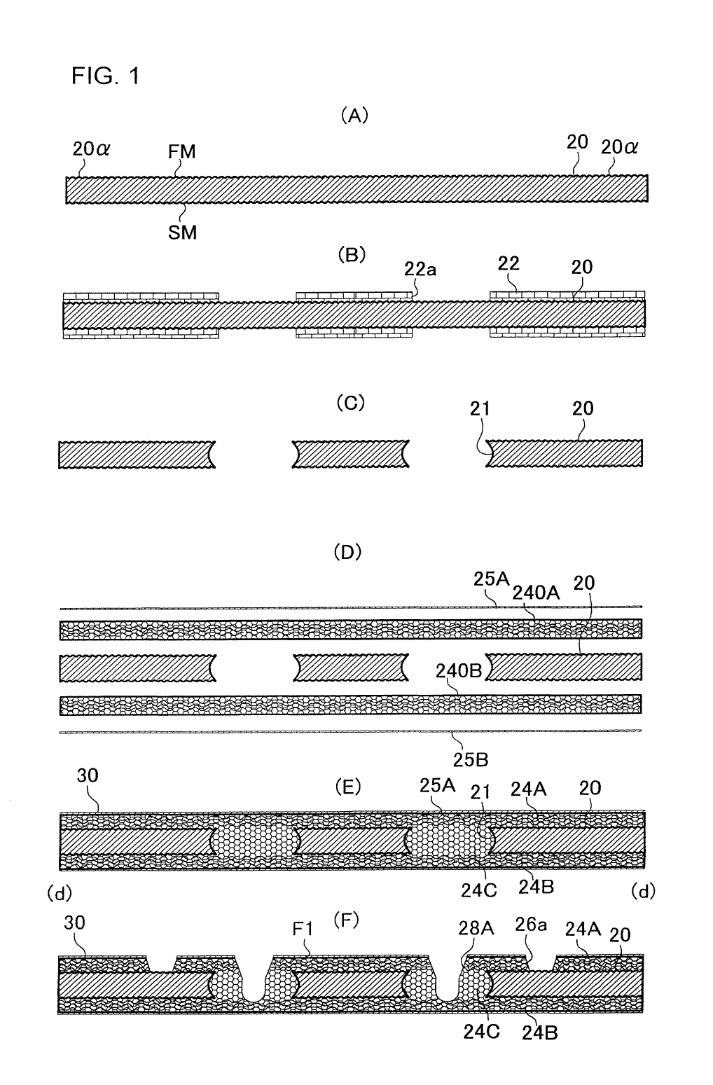

A method for manufacturing multilayer printed wiring board 10 according to the first embodiment is described with reference to FIGS. 1˜5 in the following.

Metal layer 20 with a thickness of 20˜100 μm is prepared (FIG. 1(A)). The metal layer has first surface (FM) and second surface (SM) opposite the first surface. As the metal layer, copper foil and Fe—Ni alloys such as alloy 42, alloy 36 or the like may be used. When an Fe—Ni alloy is used, 3˜15 μm-thick electrolytic copper-plated film (CuM) is formed on the surface (FIG. 12(B), (C)). Since the thermal expansion coefficient of Fe—Ni alloys is small, Fe—Ni alloys are suitable for the metal layer. The surfaces of the metal layer are roughened using a roughening solution such as an etching solution. The Rz of the first surface and the second surface is 2˜6 μm.

The Rz of the first surface and the Rz of the second surface may be different. In such a case, a protective film is laminated on the second surface of the metal layer. Then, the first surface of the metal layer is roughened using a roughening solution. The Rz of the first surface of the metal layer is 3.5˜6 μm. After that, the protective film is removed from the second surface, and a protective film is laminated on the first surface. The second surface of the metal layer is roughened using a roughening solution. The Rz of the second surface of the metal layer is 2˜3 μm. Then, the protective film is removed from the first surface (FIG. 12(C)). In such a case, an IC chip is mounted on the first-surface side of the metal layer.

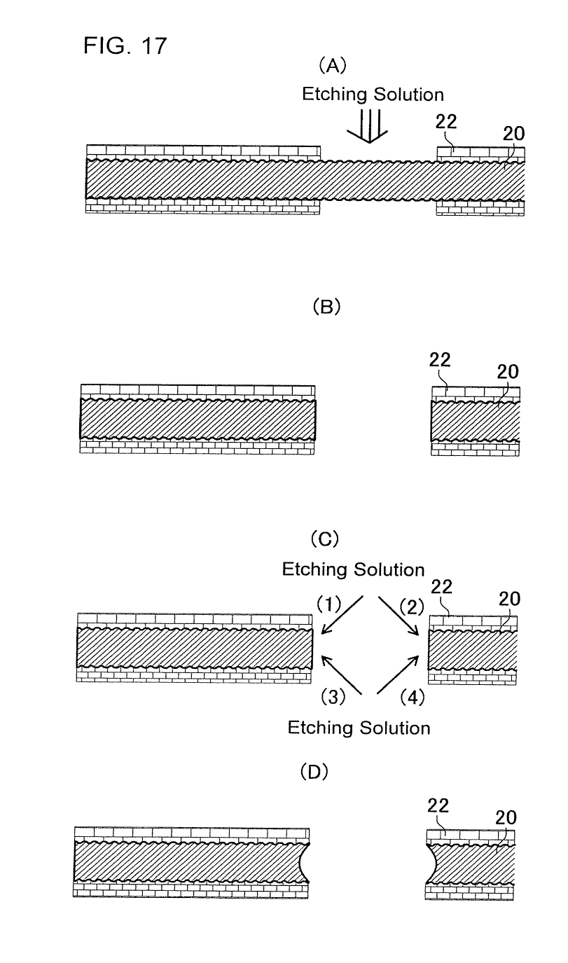

As shown in FIG. 1(B), etching resist 22 is formed on both surfaces of the metal layer. The metal layer is removed from portions left exposed by the etching resist using an etching solution. Opening 21 is formed in the metal layer (FIG. 1(C)). Opening 21 penetrates through the metal layer. The etching resist is removed. The shape of side walls (wall surfaces) of the metal layer exposed through opening 21 is adjusted by etching conditions and etching methods. An example is shown in the following (FIG. 17). An etching solution is sprayed onto the metal layer from one side of the metal layer using a perpendicular nozzle (FIG. 17(A)). Instead of etching, opening 21 may be formed by mechanical processing using a laser, a router or the like. Wall surfaces of the metal layer are substantially perpendicular (FIG. 17(B)). Then, the etching solution is sprayed diagonally onto the wall surfaces. The etching solution is sprayed onto the wall surfaces from both surfaces of the metal layer (FIG. 17(C)). The wall surfaces of the metal layer become curved (FIG. 17(D)). In FIG. 17(C), (1), (2), (3) and (4) schematically show directions of the etching solution to be sprayed. In FIG. 17(C), (1), (2), (3) and (4) may each be sprayed one by one. By adjusting the spraying pressure and time, (Re) and the shape are adjusted.

A coupling agent is applied on the first surface, second surface and wall surfaces of the metal layer. Adhesive intensity increases between resin insulation layers and filler resin and the metal layer.

Prepregs (240A, 240B) and copper foils (25A, 25B) are laminated on the first surface and second surface of the metal layer (FIG. 1(D)). The metal layer, prepregs and copper foils are integrated through thermal pressing. During that time, resin of the prepreg seeps into opening 21, and opening 21 is filled with resin. Simultaneously, the resin in the prepreg and the opening is cured. First resin insulation layer (24A) is formed on the first surface of the metal layer, second resin insulation layer (24B) is formed on the second surface of the metal layer, and filler resin (24C) is formed in the opening (FIG. 1(E)). The first and second resin insulation layers contain reinforcing material such as glass cloth, inorganic particles such as glass and resin such as epoxy. If the prepreg contains inorganic particles such as glass, opening 21 is filled with resin containing inorganic particles.

Openings are formed in copper foils (25A, 25B) (not shown in the drawings). The opening in copper foil (25A) and the opening in copper foil (25B) are formed on the filler resin.

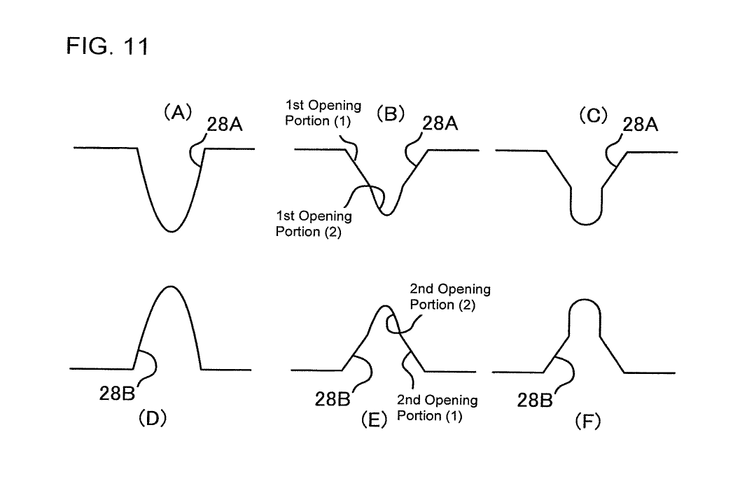

From the upper surface (F1 side) of the first resin insulation layer, a CO2 laser is irradiated at the first resin insulation layer exposed through an opening in copper foil (25A). First opening portion (28A) is formed to penetrate through the first resin insulation layer and reach inside the filler resin (FIG. 1(F)). The first opening portion is formed by two pulses, for example. The laser diameter of the first pulse is greater than the laser diameter of the second pulse. Thus, the first opening portion becomes thinner from the upper surface of the first resin insulation layer toward the main surface of the second resin insulation layer. However, the number of laser pulses and the pulse width are not limited specifically. The laser intensity is preferred to be greater in the center than on the periphery. The opening portion tends to be formed in a tapering shape. Examples of the first opening portion are shown in FIG. 11. In FIG. 11(A), the first opening portion becomes gradually thinner. In FIG. 11(B), the first opening portion is bent at a predetermined location. In FIG. 11(C), the first opening portion is bent at a predetermined location, and the shape of the first opening portion beyond the bent portion is substantially straight. FIGS. 11(A), (B) and (C) are examples of the first opening portion in the first embodiment. Opening (26a) reaching the metal layer is formed in the first resin insulation layer according to requirements.

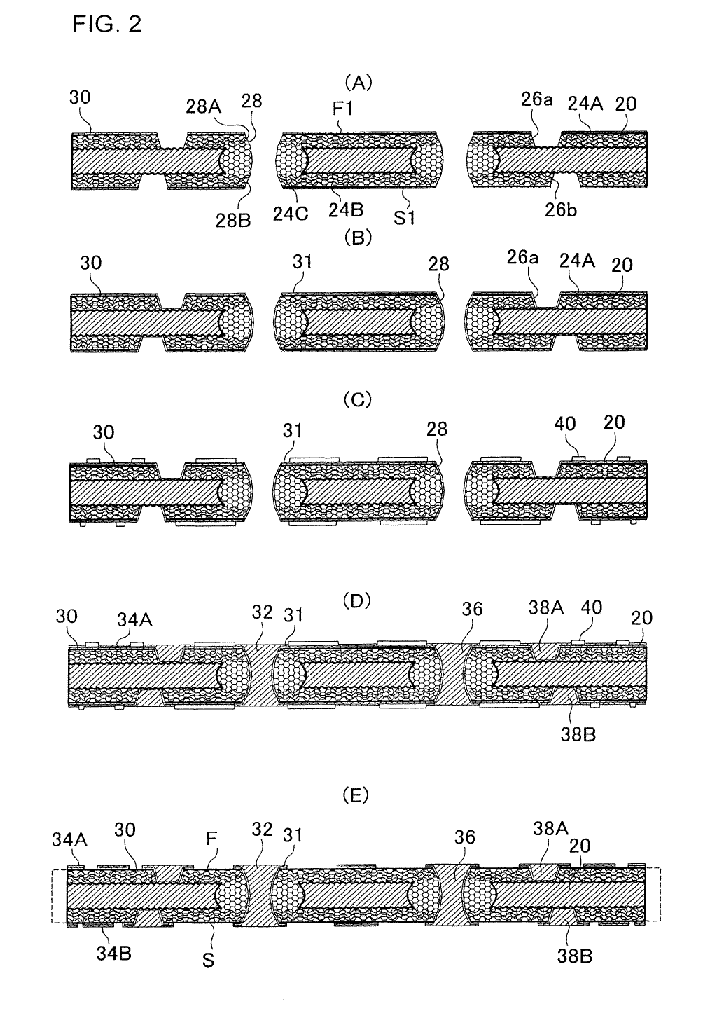

From the main surface (S1 side) of the second resin insulation layer, a CO2 laser is irradiated at the second resin insulation layer exposed through an opening in copper foil (25B). Second opening portion (28B) is formed to penetrate through the second resin insulation layer and reach inside the filler resin. The second opening portion is connected to the first opening portion in the filler resin to form penetrating hole 28 (FIG. 2(A)). The second opening portion is formed by two pulses, for example. The laser diameter of the first pulse is greater than the laser diameter of the second pulse. Thus, the second opening portion becomes thinner from the main surface of the second resin insulation layer toward the upper surface of the first resin insulation layer. However, the number of laser pulses and the pulse width are not limited specifically. In FIG. 11(D), the second opening portion becomes gradually thinner. In FIG. 11(E), the second opening portion is bent at a predetermined location. In FIG. 11(F), the second opening portion is bent at a predetermined location, and the shape of the second opening portion beyond the bent portion is substantially straight. FIGS. 11(D), (E) and (F) are examples of the second opening portion in the first embodiment. Opening (26b) reaching the metal layer is formed in the second resin insulation layer according to requirements.

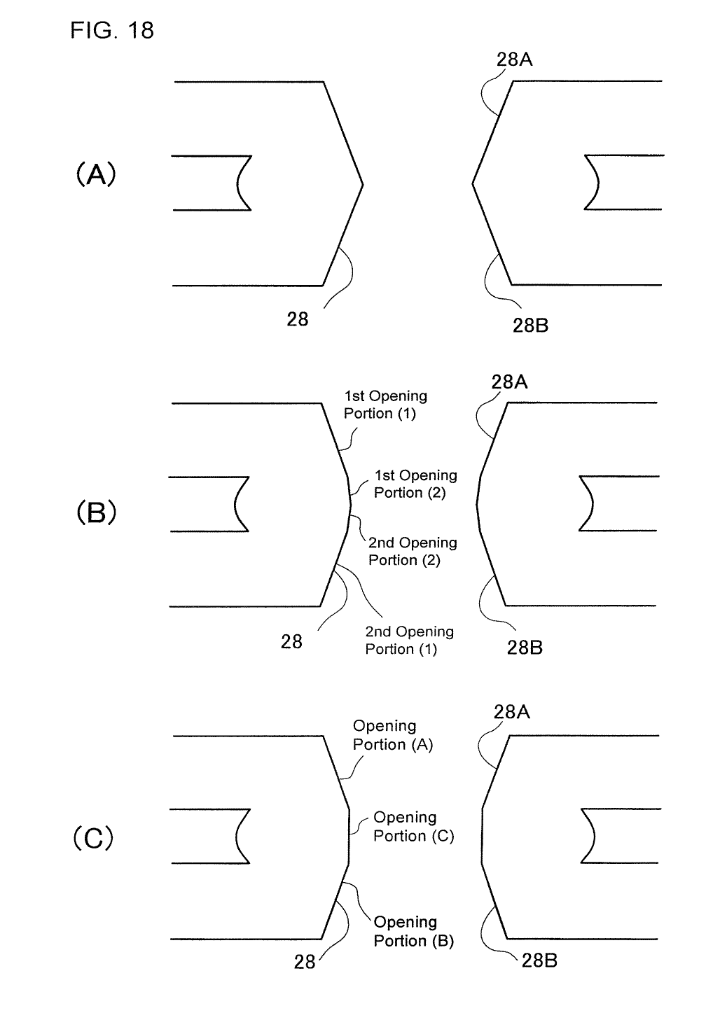

FIG. 18 shows examples of penetrating hole 28 of the first embodiment. In FIG. 18(A), penetrating hole 28 is formed with a first opening portion gradually becoming thinner and a second opening portion gradually becoming thinner. In FIG. 18(B), penetrating hole 28 is formed with a first opening portion shown in FIG. 11(B) and a second opening portion shown in FIG. 11(E). In FIG. 13(C), penetrating hole 28 is formed with a first opening portion shown in FIG. 11(C) and a second opening portion shown in FIG. 11(F). In the penetrating hole in FIG. 18(C), opening portion (A) which gradually becomes thinner from the first surface of the core substrate toward the second surface, and opening portion (B) which gradually becomes thinner from the second surface of the core substrate toward the first surface are connected by opening portion (C) which has a substantially straight shape. Opening portion (A) is formed in the first resin insulation layer, opening portion (B) is formed in the second resin insulation layer, and opening portion (C) is formed in the filler resin. FIGS. 11(A), (B) and (C) are included as penetrating holes of the first embodiment.

The connected portion of the first opening portion and the second opening portion may be positioned at the center of the core substrate in a cross-sectional direction, or may be positioned off the center.

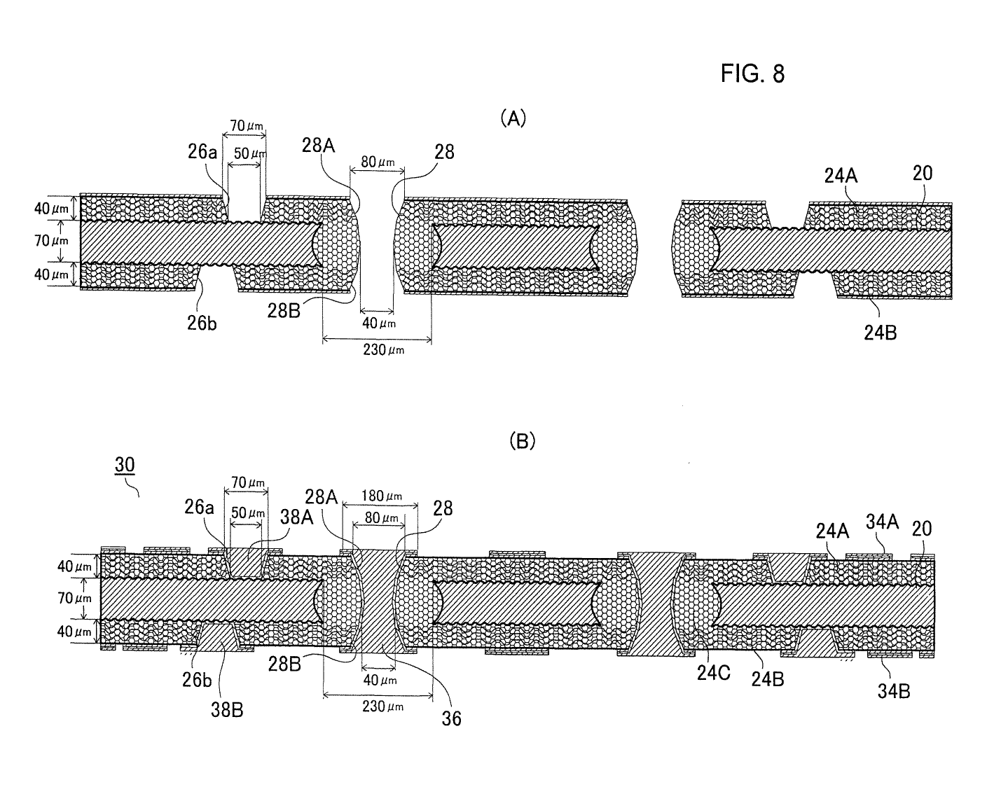

FIG. 8(A) shows a magnified view of core substrate 30 having penetrating hole 28. The first opening portion is made up of first opening portion (1) and first opening portion (2) (see FIGS. 11, 18). The penetrating hole in FIG. 8 is shaped the same as that in FIG.

18(B). First opening portion (1) is formed in the first resin insulation layer and first opening portion (2) is formed in the filler resin. When the degree at which an opening portion becomes thinner from the first surface of the core substrate toward the second surface is compared in first opening portion (1) and first opening portion (2), it is greater in first opening portion (1) than in first opening portion (2). Also, the second opening portion is made up of second opening portion (1) and second opening portion (2) (see FIGS. 11, 18). Second opening portion (1) is formed in the second resin insulation layer and second opening portion (2) is formed in the filler resin. When the degree at which an opening portion becomes thinner from the second surface of the core substrate toward the first surface is compared in second opening portion (1) and second opening portion (2), it is greater in second opening portion (1) than in second opening portion (2). While the first and second resin insulation layers include reinforcing material such as glass cloth, the filler resin does not include reinforcing material. The first and second resin insulation layers are less likely to be processed by a laser than the filler resin. Accordingly, the above-described penetrating hole is formed in the first embodiment. Under predetermined conditions, opening portion (C) with a substantially straight shape is obtained (FIG. 18(C)). Since the connected portion is made thicker, the reliability of the through-hole conductor is enhanced. Also, heat dissipation improves.

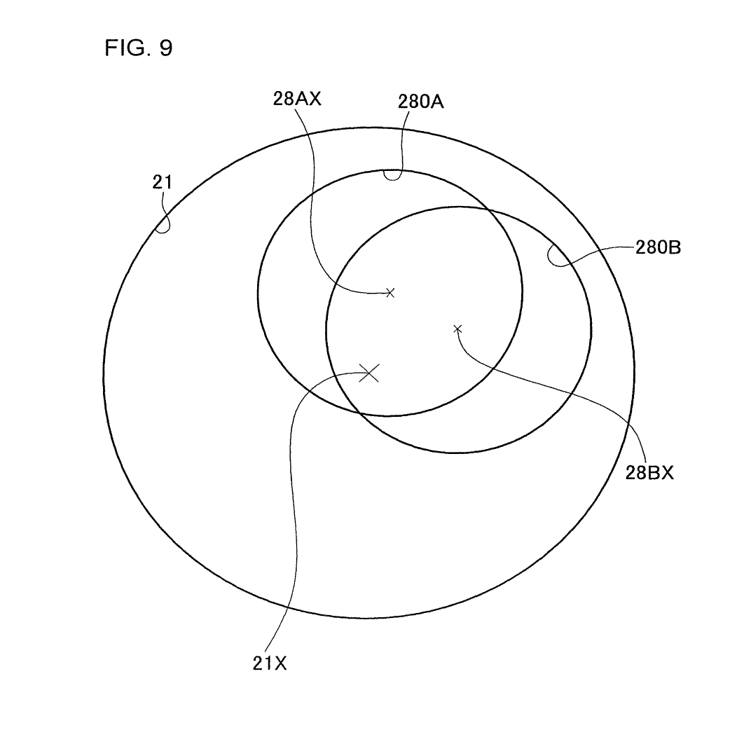

In FIG. 9, first opening (280A) and second opening (280B) are projected at equal magnification on the first surface of metal layer 20. In FIG. 9, (21X) shows the position of the gravity center of opening 21 of the metal layer, (28AX) shows the position of the gravity center of first opening (280A), and (28BX) shows the position of the gravity center of second opening (280B). In the first embodiment, each gravity center does not overlap. The reliability of the through-hole conductor is enhanced. Also, since the distance decreases between the metal layer and the through-hole conductor, heat dissipation improves. The gravity center of first opening (280A) may overlap with the gravity center of first opening (280B). Straight line (Q1) passing through the gravity center of the opening of the metal layer and perpendicular to the first surface of the core substrate is offset from straight line (Q2) passing through the gravity center of the first opening and perpendicular to the first surface of the core substrate. Straight line (Q1) passing through the gravity center of the opening of the metal layer and perpendicular to the first surface of the core substrate is offset from straight line (Q3) passing through the gravity center of the second opening and perpendicular to the first surface of the core substrate. Straight line (Q1), straight line (Q2) and straight line (Q3) may also be offset.

Electroless plating is performed and electroless plated film 31 is formed on the surfaces of the substrate having penetrating hole 28 for a through-hole conductor and via-conductor openings (26a, 26b), side surfaces of penetrating hole 28 and side surfaces of via-conductor openings (FIG. 2(B)).

Plating resist 40 is formed on the electroless plated film (FIG. 2(C)).

Electrolytic plating is performed, and electrolytic plated film 32 is formed where plating resist 40 is not formed. Simultaneously, penetrating hole 28 and via-conductor openings (26a, 26b) are filled with electrolytic plated film 32 (FIG. 2(D)).

Plating resist 40 is removed, electroless plated film 31 and copper foil exposed from electrolytic plated film 32 are etched away, conductive layers (34A, 34B), through-hole conductor 36 and via conductors (38A, 38B) are formed, and printed wiring board (core substrate) 30 is completed (FIG. 2(E)).

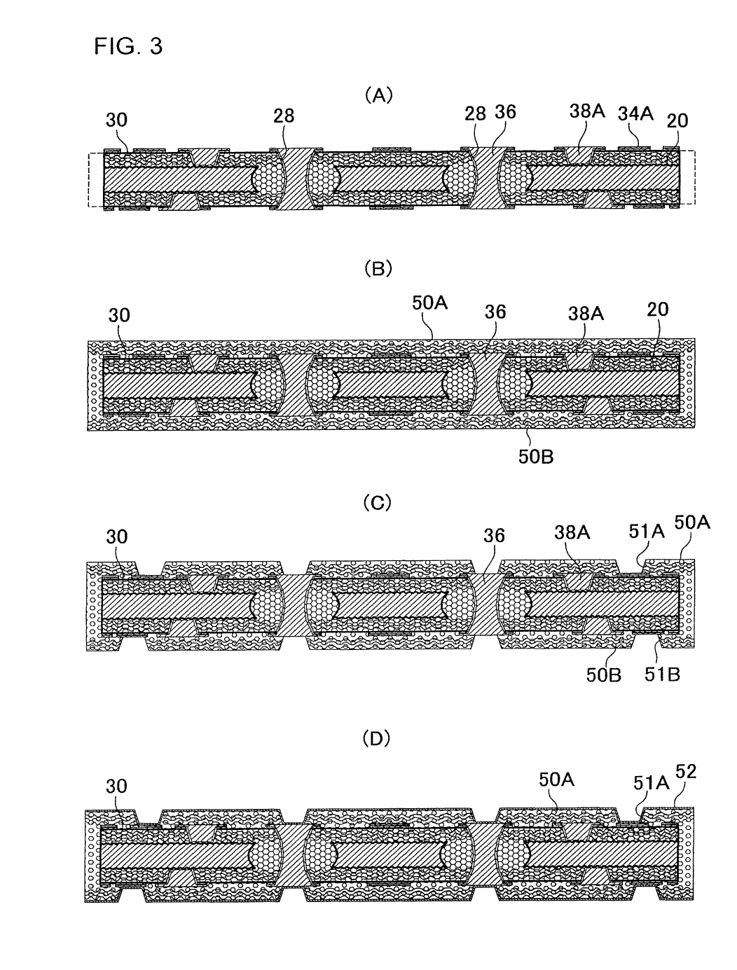

Using a drill, metal layer 20 between adjacent finished products is removed (FIG. 3(A)).

On both surfaces of core substrate 30, upper interlayer resin insulation layer (50A) and lower interlayer resin insulation layer (50B) are formed (FIG. 3(B)). During that time, cut sections formed by the above drill processing are filled with upper interlayer resin insulation layer (50A) or lower interlayer resin insulation layer (50B).

Using a CO2 laser, via-conductor openings (51A, 51B) with a diameter of 80 μm are formed in upper interlayer resin insulation layer (50A) and lower interlayer resin insulation layer (50B) (FIG. 3(C)).

Electroless plated film 52 is formed in the range of 0.1˜5 μm on the upper and lower interlayer resin insulation layers and on the inner walls of via-conductor openings (FIG. 3(D)).

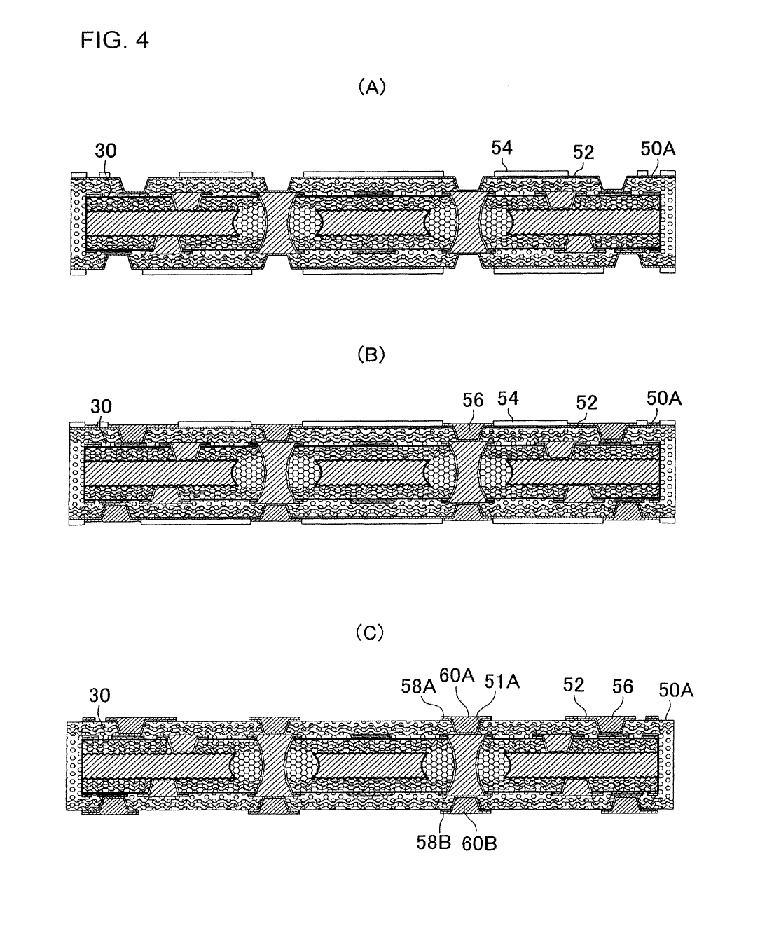

Plating resist 54 is formed on electroless plated film 52 (FIG. 4(A)).

Next, electrolytic plating is performed where the plating resist is not formed, and electrolytic plated film 56 is formed (FIG. 4(B)).

Plating resist 54 is removed. Then, electroless plated film 52 between portions of electrolytic plated film 56 is removed. Conductive circuits (58A, 58B) and via conductors (60A, 60B) made of electroless plated film 52 and electrolytic plated film 56 are formed (FIG. 4(C)).

Solder-resist layers (70A, 70B) with openings (71A, 71B) are formed (FIG. 5(A)). Multilayer printed wiring board 10 is completed.

Metal film 74 of Sn or the like is formed in openings (71A, 71B) (FIG. 5(B)). As for the metal film, a nickel-gold layer and a nickel-palladium-gold layer are listed.

A solder ball is loaded in opening (71A) and a reflow is conducted to form solder bump (76A) in opening (71A). In the same manner, solder bump (76B) is formed in opening (71B) (FIG. 6).

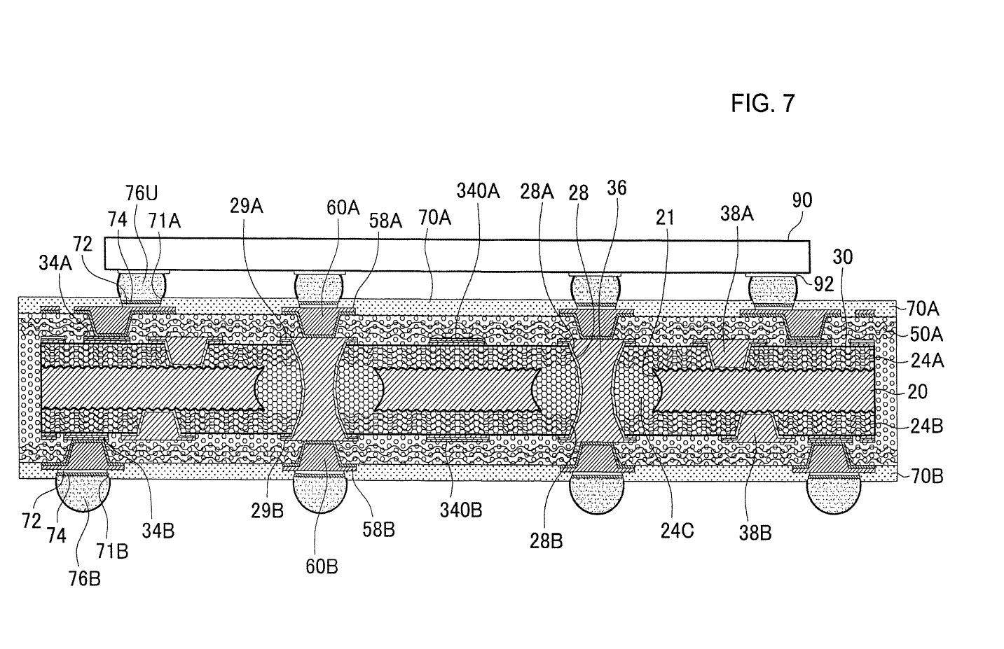

IC chip 90 is mounted on multilayer printed wiring board 10 through solder bump (76A) (FIG. 7).

### Second Embodiment

A metal layer is prepared. Etching resist is formed on the first surface and the second surface of the metal layer. The metal layer exposed from the etching resist is removed. Opening 21 is formed in the metal layer. The etching resist is removed. The first surface, second surface and wall surfaces of the metal layer are roughened. By simultaneously roughening the first surface and the second surface, the Rz is substantially the same on the first surface and the second surface. Also, the same as in the first embodiment, the first surface and the second surface may be roughened separately. The Rz of the first surface and the Rz of the second surface are different, the same as in the first embodiment. The subsequent procedures are the same as in the first embodiment.

### EXAMPLE

A 70 μm metal layer is prepared (FIG. 1(A), FIG. 8). The metal layer has a first surface and a second surface opposite the first surface. An IC chip is mounted later on the first-surface side of the metal layer. The metal layer in the example is made of 42 alloy and electrolytic copper-plated film coating the 42 alloy. The thickness of the electrolytic copper-plated film is 5 μm. A protective film is laminated on the second surface of the metal layer. Then, the first surface of the metal layer is roughened using a Cz solution made by Mec Company. The Rz of the first surface of the metal layer is 3.5˜6 μm. Next, the protective film is removed from the second surface and a protective film is laminated on the first surface. The second surface of the metal layer is roughened using a Cz solution made by Mec Company. The Rz of the second surface of the metal layer is 2˜3 μm. Then, the protective film is removed from the first surface.

As shown in FIG. 1(B), etching resist 22 is formed on both surfaces of the metal layer. The metal layer exposed from the etching resist is removed by an etching solution. Opening 21 is formed in the metal layer (FIG. 1(C)).

Next, using an etching solution and an etching method disclosed in US 2006/199394A1, a substantially straight opening is formed (FIG. 17(B)). Then, an etching solution is sprayed onto wall surfaces of the metal layer from diagonally above the first surface and the second surface of the metal layer (FIG. 17(C)). The wall surfaces of the metal layer become curved (FIG. 1(D)). The diameter of the opening is 230 μm, and the recessed amount (Re) is 20 μm. Etching resist 22 is removed (FIG. 1(C)).

Prepregs (240A, 240B) with a thickness of approximately 40 μm and copper foils (25A, 25B) with a thickness of 5 μm are laminated on the first surface and second surface of the metal layer (FIG. 1(D)). The metal layer, prepregs and copper foils are integrated through thermal pressing. At that time, resin of the prepreg seeps into opening 21, and opening 21 is filled with resin. Simultaneously, the resin in the prepregs and the opening is cured. A first resin insulation layer is formed on the first surface of the metal layer, a second resin insulation layer is formed on the second surface of the metal layer, and filler resin is formed in the opening (FIG. 1(E)). The first and second resin insulation layers contain glass cloth, glass particles and epoxy resin. The filler resin is filled with resin containing glass particles and epoxy. The thickness of the first and second resin insulation layers is 40 μm (FIG. 8).

Openings with a diameter of approximately 80 μm are formed in copper foils (25A, 25B). An opening in copper foil (25A) and an opening in copper foil (25B) are formed on the filler resin. From the upper surface (F1 side) of the first resin insulation layer, two pulses of a CO2 laser are irradiated at the first resin insulation layer exposed through the opening in copper foil (25A). The laser diameter of the first pulse is greater than the laser diameter of the second pulse. Also, the laser energy is greater in the center than on the periphery. First opening portion (28A) is formed to penetrate through the first resin insulation layer and to reach inside the filler resin (FIG. 1(F)). The first opening portion becomes thinner from the upper surface of the first resin insulation layer toward the main surface of the second resin insulation layer. Moreover, the inner walls of the first opening portion bend at the interface of the filler resin and the first resin insulation layer in a cross-sectional direction of the metal layer (FIG. 11(B)). Opening (26a) reaching the metal layer is formed in the first resin insulation layer.

From the main surface (S1 side) of the second resin insulation layer, two pulses of CO2 laser are irradiated at the second resin insulation layer exposed through the opening in copper foil (25B). The laser diameter of the first pulse is greater than the laser diameter of the second pulse. Also, the laser energy is greater in the center than on the periphery.

Second opening portion (28B) is formed to penetrate through the second resin insulation layer and reach inside the filler resin. The second opening portion is connected to the first opening portion inside the filler resin, and penetrating hole 28 is formed (FIG. 2(A)). The diameter of the first opening and the second opening is 80 μm, and the diameter of the connected portion is 40 μm (FIG. 8). The second opening portion becomes thinner from the main surface of the second resin insulation layer toward the upper surface of the first resin insulation layer. Moreover, the inner walls of the second opening portion bend at the interface of the filler resin and the second resin insulation layer in a cross-sectional direction of the metal layer (FIG. 11(E)). Opening (26b) reaching the metal layer is formed in the second resin insulation layer.

The connected portion of the first opening portion and the second opening portion are shifted from the center of the metal layer toward the first-surface side (FIG. 15(B)). Such an example is also a preferred example in each embodiment. A straight line passing through the gravity center of the first opening and perpendicular to the first surface of the core substrate is offset from a straight line passing through the gravity center of the opening of the metal layer and perpendicular to the first surface of the core substrate. Also, a straight line passing through the gravity center of the second opening and perpendicular to the first surface of the core substrate is offset from a straight line passing through the gravity center of the opening of the metal layer and perpendicular to the first surface of the core substrate (FIG. 9).

On the surfaces of the substrate having penetrating hole 28 for a through-hole conductor and via-hole openings (26a, 26b), side surfaces of penetrating hole 28 and side surfaces of via-hole openings, electroless copper plating is performed to form electroless copper-plated film 31 (FIG. 2(B)). Plating resist 40 is formed on the electroless copper-plated film (FIG. 2(C)). Electrolytic copper plating is performed to form electrolytic copper-plated film 32 where plating resist 40 is not formed. Simultaneously, penetrating hole 28 and via-hole openings (26a, 26b) are filled with electrolytic copper-plated film 32 (FIG. 2(D)).

Plating resist 40 is removed, electroless copper-plated film 31 and copper foil exposed from electrolytic plated film 32 are etched away, conductive circuits (34A, 34B), through-hole conductor 36 and via conductors (38A, 38B) are formed, and core substrate 30 is completed (FIG. 2(E)). On both surfaces of core substrate 30, upper interlayer resin insulation layer (50A) and lower interlayer resin insulation layer (50B) are formed (FIG. 3(B)).

Using a CO2 laser, 80 μm via-conductor openings (51A, 51B) are formed in upper interlayer resin insulation layer (50A) and lower interlayer resin insulation layer (50B) (FIG. 3(C)). Electroless copper-plated film 52 is formed in the range of 0.1˜5 μm on the upper and lower interlayer resin insulation layers and on the inner walls of via-conductor openings (FIG. 3(D)).

Plating resist 54 is formed on electroless copper-plated film 52 (FIG. 4(A)). Next, electrolytic plating is performed where the plating resist is not formed, and electrolytic plated film 56 is formed (see FIG. 4(B)).

Plating resist 54 is removed. Next, electroless plated film 52 between portions of electrolytic plated film 56 is removed. Conductive circuits (58A, 58B) and via conductors (60A, 60B) made of electroless plated film 52 and electrolytic plated film 56 are formed (FIG. 4(C)). Solder-resist layers (70A, 70B) with openings (71A, 71B) are formed (FIG. 5(B)). Multilayer printed wiring board 10 is completed (FIG. 5(A)).

A printed wiring board according to an embodiment of the present invention includes the following: a metal layer with a first surface and a second surface opposite the first surface and having an opening that reaches the second surface from the first surface; a filler resin filled in the opening of the metal layer; a first resin insulation layer with an upper surface and a lower surface opposite the upper surface and formed on the first surface of the metal layer and on the filler resin in such a way that the lower surface faces the first surface of the metal layer; a second resin insulation layer with a main surface and a secondary surface opposite the main surface and formed on the second surface of the metal layer and on the filler resin in such a way that the secondary surface faces the second surface of the metal layer; a first conductive layer formed on the upper surface of the first resin insulation layer; a second conductive layer formed on the main surface of the second resin insulation layer; and a through-hole conductor which is formed in a penetrating hole that penetrates through the first resin insulation layer, the filler resin and the second resin insulation layer and which connects the first conductive layer and the second conductive layer. Then, a side wall of the metal layer exposed through the opening of the metal layer is curved inward into the metal layer, the penetrating hole is made up of a first opening portion that penetrates through the first resin insulation layer and reaches inside the filler resin and of a second opening portion that penetrates through the second resin insulation layer, reaches inside the filler resin and is connected to the first opening portion in the filler resin, the first opening portion becomes thinner from the upper surface of the first resin insulation layer toward the main surface of the second resin insulation layer, and the second opening portion becomes thinner from the main surface of the second resin insulation layer toward the upper surface of the first resin insulation layer.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a core substrate having a first surface and a second surface on an opposite side of the first surface;
a first conductive layer formed on the first surface of the core substrate;
a second conductive layer formed on the second surface of the core substrate; and
a through-hole conductor formed through the core substrate and connecting the first conductive layer and the second conductive layer,
wherein the core substrate comprises an insulation structure and a metal layer positioned inside the insulation structure, the metal layer has an opening portion through which the through-hole conductor passes and has a side wall recessed into the metal layer and forming the opening portion, the insulation structure has a first resin insulation layer portion formed on one side of the metal layer, a second resin insulation layer portion formed on an opposite side of the metal layer and a filler resin portion filling the opening portion, the through-hole conductor has a first portion in the first resin insulation layer portion and a second portion in the second resin insulation layer portion, the first and second portions reach inside the filler resin portion and are connected in the filler resin portion, the first portion is tapered from the first conductive layer toward the second conductive layer, and the second portion is tapered from the second conductive layer toward the first conductive layer.

2. The printed wiring board according to claim 1, wherein the through-hole conductor comprises a plating material filling a penetrating hole formed through the core substrate.

3. The printed wiring board according to claim 1, wherein the through-hole conductor is formed in a penetrating hole formed through the core substrate, the penetrating hole has a first opening portion having an opening on a surface of the first resin insulation layer portion and a second opening portion having an opening on a surface of the second resin insulation layer portion, the opening of the first opening portion has a straight line passing through a gravity center of the opening of the first opening portion and perpendicular to the surface of the first resin insulation layer portion, and the straight line passing through the gravity center of the opening of the first opening portion is not aligned with a straight line passing through a gravity center of the opening of the second opening portion and perpendicular to the surface of the first resin insulation layer portion.

4. The printed wiring board according to claim 1, wherein the filler resin portion comprises a resin derived from at least one of the first resin insulation layer portion and the second resin insulation layer portion.

5. The printed wiring board according to claim 1, wherein the metal layer has a thickness which is in a range of 20 μm˜100 μm.

6. The printed wiring board according to claim 1, wherein the metal layer has at least one surface which is roughened and which has Rz in a range of 2.0˜6.0 μm.

7. The printed wiring board according to claim 1, wherein the metal layer has a first surface on which the first resin insulation layer portion is formed and a second surface on which the second resin insulation layer portion is formed, and the first surface of the metal layer has a roughness which is different from a roughness of the second surface of the metal layer.

8. The printed wiring board according to claim 7, wherein the roughness of the first surface of the metal layer has Rz in a range of 3.5˜6.0 μm, and the roughness of the second surface of the metal layer has Rz in a range of 2.0˜3.0 μm.

9. The printed wiring board according to claim 1, wherein the metal layer forms one of a power source line and a ground line.

10. The printed wiring board according to claim 1, wherein the first and second resin insulation layer portions include a reinforcing material, and the filler resin portion does not include a reinforcing material.

11. The printed wiring board according to claim 1, wherein the metal layer is made of one of copper and an Fe—Ni alloy.

12. The printed wiring board according to claim 1, wherein the first portion of the through-hole conductor has a bent portion at a boundary of the first resin insulation layer portion and the filler resin portion.

13. The printed wiring board according to claim 1, wherein the second portion of the through-hole conductor has a bent portion at a boundary of the second resin insulation layer portion and the filler resin portion.

14. The printed wiring board according to claim 1, wherein the first portion of the through-hole conductor has a bent portion at a boundary of the first resin insulation layer portion and the filler resin portion, and the second portion of the through-hole conductor has a bent portion at a boundary of the second resin insulation layer portion and the filler resin portion.

15. The printed wiring board according to claim 1, further comprising a via conductor formed in the first resin insulation layer portion and connecting the first conductive layer and the metal layer.

16. The printed wiring board according to claim 1, further comprising:
a first via conductor formed in the first resin insulation layer portion and connecting the first conductive layer and the metal layer; and
a second via conductor formed in the second resin insulation layer portion and connecting the second conductive layer and the metal layer.

17. The printed wiring board according to claim 1, further comprising a plated film formed on a first surface of the metal layer and a second surface of the metal layer on an opposite side of the first surface of the metal layer.

18. The printed wiring board according to claim 17, wherein the plated film has a concavo-convex pattern on at least one of the first surface and second surface of the metal layer.

19. The printed wiring board according to claim 1, further comprising an electronic component, wherein the through-hole conductor forms a signal line connected to the electronic component.

20. The printed wiring board according to claim 1, wherein the metal layer is positioned inside the insulation structure such that the metal layer is entirely covered with a resin of the insulation structure.
